(19) United States
(12) Patent Application Publication
(10) Pub. No.: US 2005/0190541 A1
(43) Pub. Date: Sep. 1, 2005

(54) Heat dissipation method for electronic apparatus

(76) Inventors: Hsiang-Hsi Yang, Kaohsiung City (TW); Chia Ching Lin, Banciao City (TW); Kuo Lung Shih, Taoyuan County (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/788,454

(22) Filed: Mar. 1, 2004

(51) Int. Cl. H05K 7/20

(52) U.S. Cl. 361/719

(57) ABSTRACT

A heat dissipation method is provided for an electronic apparatus including a housing, a circuit board mounted in the housing, and a heatsink device mounted between and rested on the housing and the circuit board. The heatsink device includes a heatsink plate having a bottom face rested on a surface of the housing, and a heat conductive plate having a bottom face rested on a top face of the heatsink plate and a top face rested on a bottom face of the circuit board. Thus, the heatsink device dissipates the heat produced by the heat sources of the circuit board largely and rapidly, thereby enhancing the heat dissipation effect of the electronic apparatus.

### BACKGROUND OF THE INVENTION

1. Field of the Invention

The present invention relates to a heat dissipation method, and more particularly to a heat dissipation method for an electronic apparatus, wherein the heat produced by the heat sources of the circuit board of the electronic apparatus is dissipated largely and rapidly.

2. Description of the Related Art

The circuit board for a computer is usually provided with a plurality of heat sources, such as the central processing unit (CPU), the north bridge, the south bridge or the like. In practice, the heat sources of the circuit board usually produce a greater heat during operation. A conventional heatsink for the computer comprises a fin type radiator mounted on the heat sources of the circuit board, and a cooling fan mounted in the housing of the computer for dissipating the heat produced by the heat sources of the circuit board. However, the heat produced by the heat sources is transmitted through the fin type radiator into the space of the housing, so that the heatsink effect of the conventional heatsink is limited, thereby decreasing the heat dissipation effect of the computer.

### SUMMARY OF THE INVENTION

The present invention is to mitigate and/or obviate the disadvantage of the conventional heatsink.

The primary objective of the present invention is to provide a heat dissipation method for an electronic apparatus, wherein the heat produced by the heat sources of the circuit board is dissipated largely and rapidly.

Another objective of the present invention is to provide an electronic apparatus, wherein the heatsink device is mounted between the housing and the circuit board, so that the heat produced by the heat sources of the circuit board during operation is transmitted from the heat conductive plate to the heatsink plate largely and rapidly and is then carried away from the housing.

A further objective of the present invention is to provide an electronic apparatus, wherein the heatsink device dissipates the heat produced by the heat sources of the circuit board largely and rapidly, thereby enhancing the heat dissipation effect of the electronic apparatus.

In accordance with one embodiment of the present invention, there is provided a heat dissipation method for an electronic apparatus comprising a housing, and a circuit board mounted in the housing, the heat dissipation method comprising the steps of:
providing a heatsink plate having a bottom face rested on a surface of the housing; and
providing a heat conductive plate having a bottom face rested on a top face of the heatsink plate and a top face rested on a bottom face of the circuit board.

In accordance with another embodiment of the present invention, there is provided an electronic apparatus comprising:
a housing;
a circuit board mounted in the housing; and
a heatsink device mounted between and rested on the housing and the circuit board.

Preferably, the heatsink device includes a heatsink plate having a bottom face rested on a surface of the housing, and a heat conductive plate having a bottom face rested on a top face of the heatsink plate and a top face rested on a bottom face of the circuit board.

Further benefits and advantages of the present invention will become apparent after a careful reading of the detailed description with appropriate reference to the accompanying drawings.

### BRIEF DESCRIPTION OF THE DRAWINGS

FIG. 1 is a partially cut-away plan cross-sectional view of an electronic apparatus in accordance with the preferred embodiment of the present invention;

FIG. 2 is an exploded perspective view of the electronic apparatus in accordance with the preferred embodiment of the present invention; and

FIG. 3 is a partially cut-away plan cross-sectional assembly view of the electronic apparatus as shown in FIG. 2.

### DETAILED DESCRIPTION OF THE INVENTION

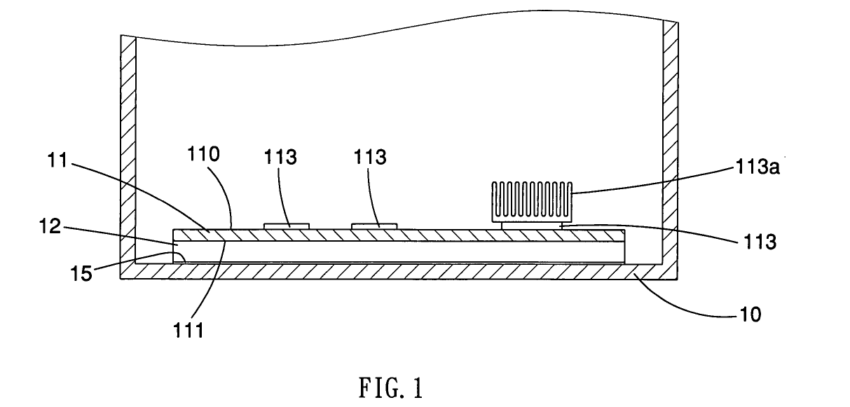

Referring to the drawings and initially to FIG. 1, an electronic apparatus in accordance with the preferred embodiment of the present invention comprises a housing 10, a circuit board 11 mounted in the housing 10, and a heatsink device 12 mounted between the housing 10 and the circuit board 11.

The housing 10 is preferably, made of metallic material, such as silver, aluminum, copper or the like.

The circuit board 11 has a top face 110 and a bottom face 111. The top face 110 of the circuit board 11 is provided with a plurality of heat sources 113, such as the central processing unit (CPU) having a specification of P4 3.0G 800F, north bridge, south bridge or the like. A fin type radiator 113a is mounted on one of the heat sources 113.

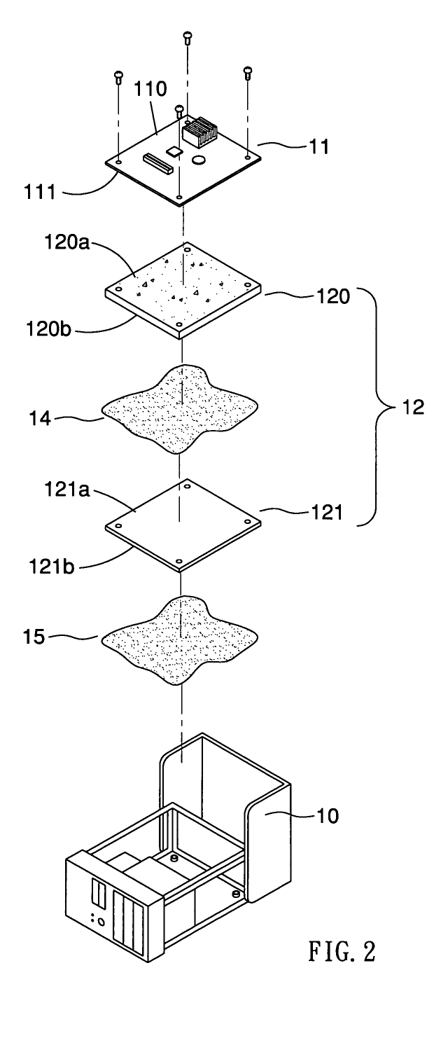

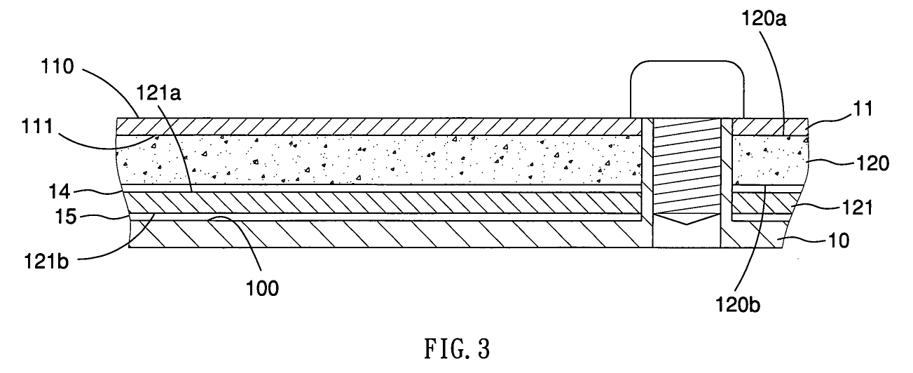

As shown in FIGS. 1-3, the heatsink device 12 includes a heatsink plate 121 having a bottom face 121b rested on a surface 100 of the housing 10, and a heat conductive plate 120 having a bottom face 120b rested on a top face 121a of the heatsink plate 121 and a top face 120a rested on the bottom face 111 of the circuit board 11.

The heat conductive plate 120 is made of a non-conducting material, such as a heat conductive rubber, soft pad or the like.

The heatsink plate 121 is preferably, made of metallic material, such as silver, aluminum, copper or the like.

In addition, the heatsink device 12 further includes a first heatsink material 15 coated between the surface 100 of the housing 10 and the bottom face 121b of the heatsink plate 121, and a second heatsink material 14 coated between the top face 121a of the heatsink plate 121 and the bottom face 120b of the heat conductive plate 120.

Preferably, each of the first heatsink material 15 and the second heatsink material 14 is a heatsink paste.

In practice, the heatsink device 12 is mounted between the housing 10 and the circuit board 11, so that the heat produced by the heat sources 113 of the circuit board 11 during operation is transmitted from the heat conductive plate 120 to the heatsink plate 121 largely and rapidly and is then carried away from the housing 10. Thus, the heatsink device 12 dissipates the heat produced by the heat sources 113 of the circuit board 11 largely and rapidly so as to reduce the temperature of the heat sources 113 of the circuit board 11 largely and rapidly, thereby enhancing the heat dissipation effect of the electronic apparatus.

The temperatures of the heat sources of the circuit board of the electronic apparatus are shown in and compared by table 1 and table 2, wherein table 1 shows the electronic apparatus without the heatsink device and table 2 shows the electronic apparatus with the heatsink device.

TABLE 1

| | IDLE | | FULL RUN | | |
|---|---|---|---|---|---|
| | Measured | | Measured | | |
| Heat | at room | Measured at | at room | Measured at | |
| source | temperature | 35° C. | temperature | 35° C. | |
| CPU | 51.9° C. | 57.9° C. | 63.7° C. | 70° | C. |
| North | 56.9° C. | 59.8° C. | 70.9° C. | 77.1° | C. |
| bridge | | | | | |
| South | 67.4° C. | 69.1° C. | 79.1° C. | 81.8° | C. |
| bridge | | | | | |
| Space | 39.9° C. | 44.4° C. | 53.5° C. | 55.8° | C. |
| in the | | | | | |
| housing | | | | | |

TABLE 2

| | IDLE | | FULL RUN | | |
|---|---|---|---|---|---|
| | Measured | | Measured | | |
| Heat | at room | Measured at | at room | | Measured at |
| source | temperature | 35° C. | temperature | | 35° C. |
| CPU | 51.9° C. | 57.8° C. | 57.2° | C. | 63.9° C. |
| North | 51.6° C. | 54.2° C. | 56° | C. | 59.8° C. |
| bridge | | | | | |
| South | 61.9° C. | 59.1° C. | 61.9° | C. | 61.6° C. |
| bridge | | | | | |
| Space | 29.4° C. | 36.2° C. | 31.6° | C. | 36.8° C. |
| in the | | | | | |
| housing | | | | | |

In conclusion, the temperatures of the heat sources 113 (including the CPU, the north bridge and the south bridge) of the circuit board 11 are reduced largely, thereby enhancing the heat dissipation effect of the electronic apparatus. In addition, the temperature in the space of the housing 10 is also reduced largely.

Although the invention has been explained in relation to its preferred embodiment(s) as mentioned above, it is to be understood that many other possible modifications and variations can be made without departing from the scope of the present invention. It is, therefore, contemplated that the appended claim or claims will cover such modifications and variations that fall within the true scope of the invention.

1. A heat dissipation method for an electronic apparatus comprising a housing, and a circuit board mounted in the housing, the heat dissipation method comprising the steps of:
step 1: providing a heatsink plate having a bottom face rested on a surface of the housing; and
step 2: providing a heat conductive plate having a bottom face rested on a top face of the heatsink plate and a top face rested on a bottom face of the circuit board.

2. The heat dissipation method in accordance with claim 1, wherein the heat conductive plate is made of a heat conductive rubber.

3. The heat dissipation method in accordance with claim 1, wherein the heat conductive plate is made of a heat conductive soft pad.

4. The heat dissipation method in accordance with claim 1, wherein each of the housing and the heatsink plate is made of silver.

5. The heat dissipation method in accordance with claim 1, wherein each of the housing and the heatsink plate is made of aluminum.

6. The heat dissipation method in accordance with claim 1, wherein each of the housing and the heatsink plate is made of copper.

7. The heat dissipation method in accordance with claim 1, further comprising the step of providing a heatsink material coated between the surface of the housing and the bottom face of the heatsink plate.

8. The heat dissipation method in accordance with claim 7, wherein the heatsink material is a heatsink paste.

9. The heat dissipation method in accordance with claim 1, further comprising the step of providing a heatsink material coated between the top face of the heatsink plate and the bottom face of the heat conductive plate.

10. The heat dissipation method in accordance with claim 9, wherein the heatsink material is a heatsink paste.

11. An electronic apparatus comprising:
a housing;
a circuit board mounted in the housing; and
a heatsink device mounted between and rested on the housing and the circuit board.

12. The electronic apparatus in accordance with claim 11, wherein the heatsink device includes a heatsink plate having a bottom face rested on a surface of the housing, and a heat conductive plate having a bottom face rested on a top face of the heatsink plate and a top face rested on a bottom face of the circuit board.

13. The electronic apparatus in accordance with claim 12, wherein the heatsink device further includes a heatsink material coated between the surface of the housing and the bottom face of the heatsink plate.

14. The electronic apparatus in accordance with claim 13, wherein the heatsink material is a heatsink paste.

15. The electronic apparatus in accordance with claim 12, wherein the heatsink device further includes a heatsink material coated between the top face of the heatsink plate and the bottom face of the heat conductive plate.

16. The electronic apparatus in accordance with claim 15, wherein the heatsink material is a heatsink paste.

17. The electronic apparatus in accordance with claim 12, wherein the heat conductive plate is made of a heat conductive rubber or soft pad.

18. The electronic apparatus in accordance with claim 12, wherein each of the housing and the heatsink plate is made of silver.

19. The electronic apparatus in accordance with claim 12, wherein each of the housing and the heatsink plate is made of aluminum.

20. The electronic apparatus in accordance with claim 12, wherein each of the housing and the heatsink plate is made of copper.
